(19) United States
(12) Patent Application Publication
(10) Pub. No.: US 2026/0322373 A1
(43) Pub. Date: Oct. 15, 2026

(54) SWITCHING CONTROL CIRCUIT AND SEMICONDUCTOR DEVICE

(71) Applicant: FUJI ELECTRIC CO., LTD., Kawasaki-shi (JP)

(72) Inventors: Takato SUGAWARA, Matsumoto-city (JP); Hidetomo OHASHI, Matsumoto-city (JP)

(73) Assignee: FUJI ELECTRIC CO., LTD., Kawasaki-shi (JP)

(21) Appl. No.: 19/465,105

(22) Filed: Jan. 30, 2026

(30) Foreign Application Priority Data
Mar. 17, 2025 (JP) 2025-042208

(51) Int. Cl. H03K 17/16; H03K 17/20

(52) U.S. Cl. CPC H03K 17/162; H03K 17/20; H03K 2217/0027; H03K 2217/0063; H03K 2217/0072

(57) ABSTRACT

A switching control circuit including: a signal output circuit outputting a set or reset signal to turn on or off the first switching device, in response to a first input signal going to a first or second logic level, respectively; a level shifter circuit level-shifting the set and reset signals; a first line to which the first and second switching devices are coupled; a first driver circuit coupled to the first line and driving the first switching device; a determination circuit determining whether the first line is in a first or second state; and a detection circuit detecting whether a time period for which the first line is in the first state after the first input signal turns to the second logic level reaches a predetermined time period. The signal output circuit outputs the reset signal, in response to the time period reaching the predetermined time period.

### CROSS-REFERENCE TO RELATED APPLICATION

This application claims priority pursuant to 35 U.S.C. §119 from Japanese Patent Application No. 2025-042208, filed on Mar. 17, 2025, the entirety of which is incorporated herein by reference.

### BACKGROUND

### Technical Field

The present invention relates to a switching control circuit and a semiconductor device.

### Related Art

There is a load driver circuit including a high-side switching device and a low-side switching device and configured to drive a load (for example, International Publication No. WO2015/045534).

In a typical load driver circuit, due to the influence of the load, wiring, and the like, noise such as a negative voltage may occur at a node to which the high-side switching device and the low-side switching device are coupled. If such noise or the like occurs, the high-side switching device may fail to be turned off at appropriate timing.

### SUMMARY

An aspect of the present disclosure is a switching control circuit configured to complementarily turn on and off a first switching device on a power supply side, and a second switching device on a ground side, the second switching device being configured to drive a load with the first switching device, the switching control circuit comprising: a signal output circuit configured to receive a first input signal, output a set signal to turn on the first switching device, in response to a first input signal turning to a first logic level, and output a reset signal to turn off the first switching device, in response to the first input signal turning to a second logic level; a level shifter circuit configured to level-shift the set signal and the reset signal; a first line to which the first switching device and the second switching device are coupled; a first driver circuit coupled to the first line, and configured to drive the first switching device based on an output from the level shifter circuit; a determination circuit configured to determine whether the first line is in a first state, in which the first switching device is on, or a second state, in which the second switching device is on; and a detection circuit configured to detect whether a time period, for which the first line is in the first state after the first input signal turns to the second logic level, reaches a predetermined time period, the signal output circuit being configured to output the reset signal, in response to the time period reaching the predetermined time period.

An aspect of the present disclosure is a semiconductor device, comprising: a first switching device on a power supply side of the semiconductor device; a second switching device on a ground side of the semiconductor device, the second switching device being configured to drive a load of the semiconductor device with the first switching device; and a switching control circuit configured to complementarily turn on and off the first and second switching devices, the switching control circuit including a signal output circuit configured to output a set signal to turn on the first switching device, in response to a first input signal turning to a first logic level, and output a reset signal to turn off the first switching device, in response to the first input signal turning to a second logic level, a level shifter circuit configured to level-shift the set signal and the reset signal, a first line to which the first switching device and the second switching device are coupled, a first driver circuit coupled to the first line, and configured to drive the first switching device based on an output from the level shifter circuit, a determination circuit configured to determine whether the first line is in a first state, in which the first switching device is on, or a second state, in which the second switching device is on, and a detection circuit configured to detect whether a time period, for which the first line is in the first state after the first input signal turns to the second logic level, reaches a predetermined time period, the signal output circuit being configured to output the reset signal in response to the time period reaching the predetermined time period.

### BRIEF DESCRIPTION OF THE DRAWINGS

FIG. 1 is a diagram illustrating an example of a semiconductor module 10.

FIG. 2 is a diagram for explaining some of main signals of a switching control circuit 23.

FIG. 3 is a diagram illustrating an example of a signal output circuit 30.

FIG. 4 is a diagram illustrating an example of a determination circuit 54.

FIG. 5 is a diagram illustrating an example of a detection circuit 55.

FIG. 6 is a diagram illustrating an example of a timer circuit 90.

FIG. 7 is a diagram for explaining a typical operation of the switching control circuit 23.

FIG. 8 is a diagram for explaining an operation of the switching control circuit 23 when noise occurs in a line Lb.

FIG. 9 is a diagram for explaining an operation of the switching control circuit 23 when noise occurs in a line Ls.

FIG. 10 is a diagram illustrating an example of a semiconductor module 11.

FIG. 11 is a diagram illustrating an example of a timer circuit 95.

### DETAILED DESCRIPTION

At least the following matters will be apparent from description of the present specification and the attached drawings. Hereinafter, identical or equivalent components, members, and the like illustrated in the drawings are denoted by the same reference numerals, and a repeated description thereof may be omitted as appropriate.

### Semiconductor Module 10

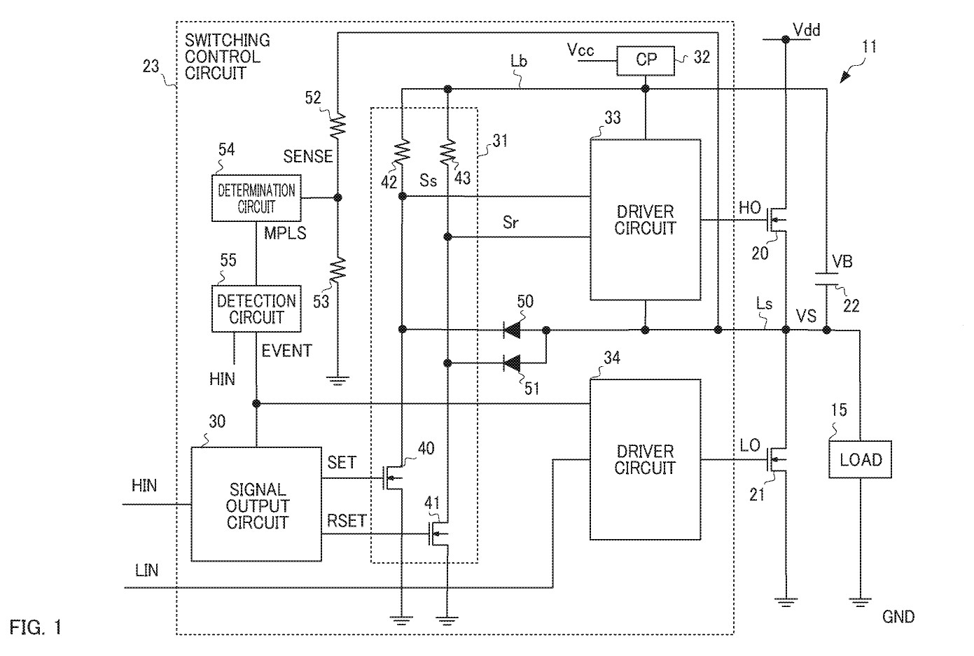

FIG. 1 is a diagram for explaining an example of a semiconductor module 10 in a first embodiment.

The semiconductor module 10 is a semiconductor device configured to drive a load 15 such as a coil based on an instruction from a microcomputer (not illustrated), and includes N-channel metal–oxide–semiconductor (NMOS) transistors 20 and 21, a capacitor 22, and a switching control circuit 23.

The NMOS transistor 20 is a switching device configured to drive the load 15 with the NMOS transistor 21. The NMOS transistor 20 is a switching device on a high side (i.e., a power supply side), whereas the NMOS transistor 21 is a switching device on a low side (i.e., a ground side). In this embodiment, a drain electrode of the NMOS transistor 21 is coupled to a source electrode of the NMOS transistor 20, and thus the NMOS transistors 20 and 21 configure a push-pull circuit.

Here, a voltage of a line Ls to which the NMOS transistor 20 and the NMOS transistor 21 are coupled is referred to as a voltage VS. In this embodiment, when the NMOS transistor 20 is turned on while the NMOS transistor 21 is off, the voltage VS results in a power supply voltage Vdd to be applied to the NMOS transistor 20. The line Ls corresponds to a "first line".

On the other hand, when the NMOS transistor 21 is turned on while the NMOS transistor 20 is off, the voltage VS results in a ground voltage (i.e., 0 V). In this embodiment, the load 15 is driven with the voltage VS applied to the load 15 resulting in the power supply voltage Vdd or the ground voltage.

The NMOS transistors 20 and 21 are MOS transistors herein, but for example, insulated gate bipolar transistors (IGBTs) or bipolar transistors may be used. The NMOS transistor 20 to which the power supply voltage Vdd is applied corresponds to a "first switching device on a power supply side", and the NMOS transistor 21 coupled to the ground corresponds to a "second switching device on a ground side".

The capacitor 22 is a device for bootstrap in which a power supply voltage VB on a high side is generated. The capacitor 22 is charged while the NMOS transistor 21 is on and the voltage VS of the line Ls is the ground voltage.

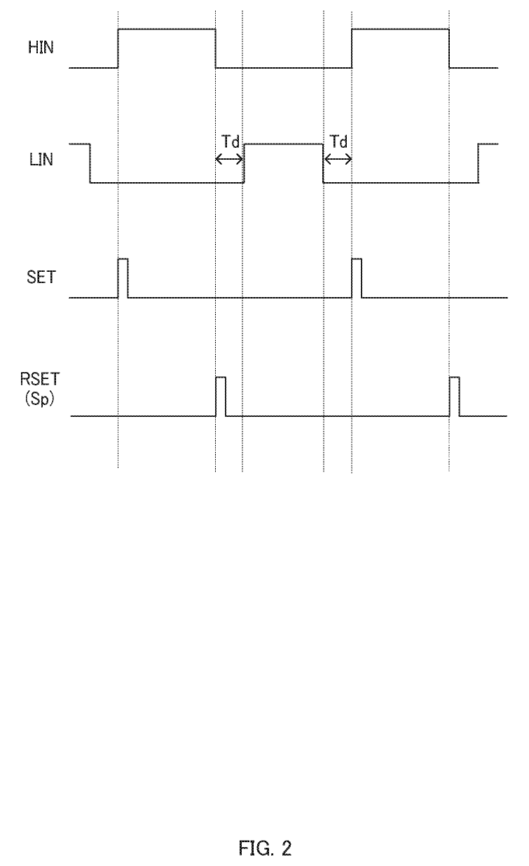

The switching control circuit 23 is a circuit configured to complementarily switch the NMOS transistors 20 and 21 based on, for example, signals HIN and LIN from the microcomputer (not illustrated). The switching control circuit 23 turns on the high-side NMOS transistor 20 for a time period during which the signal HIN is at a high level (hereinafter referred to as high or high level), and turns on the low-side NMOS transistor 21 for a time period during which the signal LIN is high. In this embodiment, as illustrated in FIG. 2, a time period Td during which both of the NMOS transistors 20 and 21 are off (i.e., a time period corresponding to a dead time) is set.

The switching control circuit 23 includes a signal output circuit 30, a level shifter circuit 31, a charge pump circuit 32, driver circuits 33 and 34, diodes 50 and 51, resistors 52 and 53, a determination circuit 54, and a detection circuit 55.

### Signal Output Circuit 30

As illustrated in FIG. 2, the signal output circuit 30 outputs a set signal SET to turn on the NMOS transistor 20 when the signal HIN goes high, and outputs a reset signal RSET to turn off the NMOS transistor 20 in response to the signal HIN going low (hereinafter referred to as low or low level). In this embodiment, both of the set signal SET and the reset signal RSET are high pulse signals.

In this embodiment, the signal HIN corresponds to a "first input signal" and the signal LIN corresponds to a "second input signal". In the signal HIN, the high level corresponds to a "first logic level" and the low level corresponds to a "second logic level".

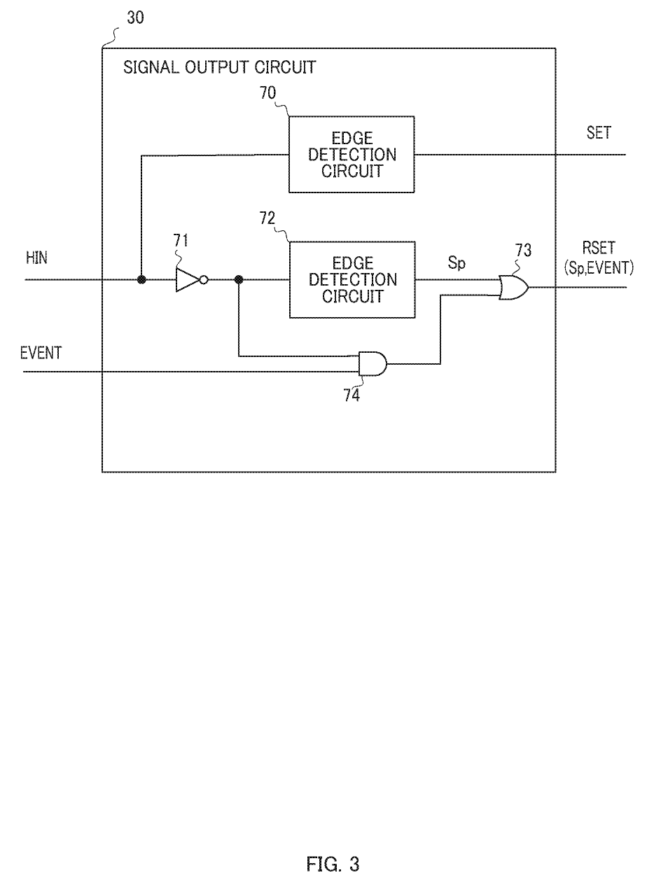

FIG. 3 is a diagram illustrating an example of the signal output circuit 30. The signal output circuit 30 includes edge detection circuits 70 and 72, an inverter 71, an OR circuit 73, and an AND circuit 74.

The edge detection circuit 70 is a circuit configured to detect a rising edge of the signal HIN and outputs a high pulsed set signal SET (see FIG. 2). The timing of the rising edge of the signal HIN is the timing at which the signal HIN changes from low to high.

The inverter 71 is a circuit configured to invert the logic level of the signal HIN and output the resultant signal. The edge detection circuit 72 is a circuit configured to detect a rising edge of the signal from the inverter 71 and output a high pulse signal Sp, as in the edge detection circuit 70. Accordingly, the edge detection circuit 72 substantially detects the timing of the falling edge of the signal HIN (that is, the timing at which the signal HIN changes from high to low).

The OR circuit 73 performs a logical OR of the pulse signal Sp from the edge detection circuit 72 and an output from the AND circuit 74, and outputs the result as the reset signal RSET. FIG. 2 illustrates an example in which the high pulse signal Sp is outputted as the reset signal RSET. The AND circuit 74 performs a logical AND of the output from the inverter 71 and a signal EVENT from the detection circuit 55, which will be described later.

### Level Shifter Circuit 31, Charge Pump Circuit 32, and Driver Circuit 34

The level shifter circuit 31 in FIG. 1 is a circuit configured to level-shift the set signal SET and the reset signal RSET and output the resultant signals, and includes NMOS transistors 40 and 41 and resistors 42 and 43. Each of a set of the NMOS transistor 40 and the resistor 42 and a set of the NMOS transistor 41 and the resistor 43 configures an inverter to invert the logic level of an inputted signal and output the result signal. In this embodiment, the level-shifted set signal SET is referred to as a set signal Ss, and the level-shifted reset signal RSET is referred to as a reset signal Sr.

While the voltage VS of the line Ls is the ground voltage, the charge pump circuit (CP) 32 charges the capacitor 22 in order to generate a power supply voltage for a high-side driver circuit 33 (described later). The charge pump circuit 32 generates the voltage for charging the capacitor 22 based on a power supply voltage Vcc. In this embodiment, the charge voltage for the capacitor 22 is referred to as a voltage VB, and a power supply line to which the voltage VB is applied is referred to as a line Lb. The line Lb corresponds to a "second line".

The driver circuit 33 outputs a high drive signal HO in response to the set signal Ss, thereby turning on the NMOS transistor 20. On the other hand, the driver circuit 33 outputs a low drive signal HO in response to the reset signal Sr, thereby turning off the NMOS transistor 20. In this embodiment, the driver circuit 33 is coupled between the line Ls and the line Lb. Then, the driver circuit 33 operates by using the voltage VS of the line Ls as a reference potential and using the voltage VB as a power supply voltage.

The driver circuit 34 drives the NMOS transistor 21 in response to the signal LIN from the microcomputer (not illustrated) and the signal EVENT. Specifically, when the high signal LIN is inputted to the driver circuit 34, the driver circuit 34 outputs a high drive signal LO, thereby turning on the NMOS transistor 21. On the other hand, when the low signal LIN is inputted to the driver circuit 34, the driver circuit 34 outputs a low drive signal LO, thereby turning off the NMOS transistor 21. In addition, the driver circuit 34 turns off the NMOS transistor 21 in response to the signal EVENT.

In this embodiment, the driver circuit 33 corresponds to a "first driver circuit" and the driver circuit 34 corresponds to a "second driver circuit".

An anode of the diode 50 is coupled to the line Ls and a cathode thereof is coupled to a drain electrode of the NMOS transistor 40. Meanwhile, an anode of the diode 51 is coupled to the line Ls and a cathode thereof is coupled to a drain electrode of the NMOS transistor 41. This configuration makes it possible to prevent an overvoltage generated in the level shifter circuit 31 from being applied to the driver circuit 33.

### Resistors 52 and 53 and Determination Circuit 54

The resistors 52 and 53 configure a voltage divider circuit to divide the voltage VS, thereby generating a voltage SENSE. The determination circuit 54 is a circuit configured to determine whether the state of the line Ls is a state where the high-side NMOS transistor 20 is on (hereinafter referred to as a state A) or a state where the low-side NMOS transistor 21 is on (hereinafter referred to as a state B). The state A corresponds to a "first state" and the state B corresponds to a "second state".

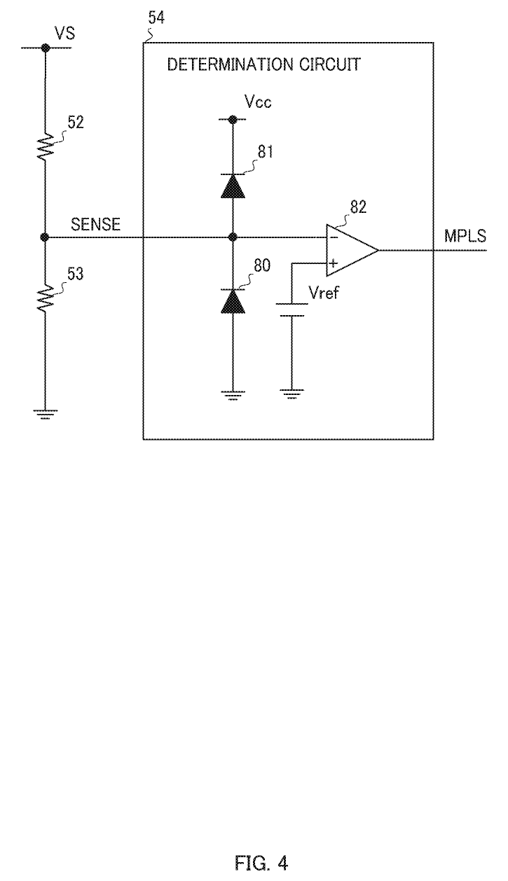

As illustrated in FIG. 4, the determination circuit 54 includes diodes 80 and 81 and a comparator 82. Both of the diodes 80 and 81 are devices configured to protect an inverting input terminal of the comparator 82.

In this embodiment, the voltage SENSE is applied to the inverting input terminal of the comparator 82. A cathode of the diode 80 is coupled to the inverting input terminal of the comparator 82 and an anode of the diode 80 is grounded. Thus, even when the voltage of the inverting input terminal of the comparator 82 drops below the ground voltage due to noise or the like, the voltage of the inverting input terminal of the comparator 82 is clamped at -Vf. Here, "Vf" is a forward voltage of the diodes 80 and 81.

The power supply voltage Vcc is applied to a cathode of the diode 81, and an anode of the diode 81 is coupled to the inverting input terminal of the comparator 82. Thus, even when the voltage of the inverting input terminal of the comparator 82 rises above the power supply voltage Vcc due to noise or the like, the voltage of the inverting input terminal of the comparator 82 is clamped at Vcc+Vf.

The comparator 82 determines whether the voltage VS of the line Ls is the voltage Vdd or the ground voltage (0 V) based on the magnitude between the voltage SENSE or a reference voltage Vref. In this embodiment, the reference voltage Vref is set to be lower than the voltage SENSE when the NMOS transistor 20 is on and the voltage VS is the voltage Vdd. On the other hand, the reference voltage Vref is set to be higher than the voltage SENSE when the NMOS transistor 21 is on and the voltage VS is the ground voltage.

Accordingly, when the voltage SENSE is higher than the reference voltage Vref because the voltage VS is the power supply voltage Vdd (that is, in the case of the state A), the comparator 82 outputs a low signal MPLS. On the other hand, when the voltage SENSE is lower than the reference voltage Vref because the voltage VS is the ground voltage (that is, in the case of the state B), the comparator 82 outputs a high signal MPLS.

### Detection Circuit 55

The detection circuit 55 is a circuit configured to detect whether the high-side NMOS transistor 20 continuously remains on even though the signal HIN enters the state where the NMOS transistor 20 is to be turned off. Specifically, the detection circuit 55 detects whether the state (that is, the state A) where the voltage SENSE is higher than the reference voltage Vref reaches a predetermined time period Ta after the signal HIN goes low.

Here, when the signal HIN goes low, the reset signal RSET is generated and thus the high-side NMOS transistor 20 is usually turned off. However, the transmission of the reset signal RSET from the level shifter circuit 31 to the driver circuit 33 may fail due to, for example, influence of noise. In this case, even though the reset signal RSET is generated, the NMOS transistor 20 continuously remains on and the voltage VS does not fall to the ground voltage.

For example, the detection circuit 55 in this embodiment is capable of detecting that the reset signal RSET is not properly transmitted to the driver circuit 33 by measuring a time period corresponding to the state A (that is, the state where the high-side NMOS transistor 20 continuously remains on) even though the signal HIN goes low, as described above.

The detection circuit 55 includes a timer circuit 90, an inverter 91, and an edge detection circuit 92.

The timer circuit 90 outputs a low signal MPLS2, in response to a time period for which the low signal MPLS is outputted in a state where the signal HIN is low reaching a predetermined period Ta.

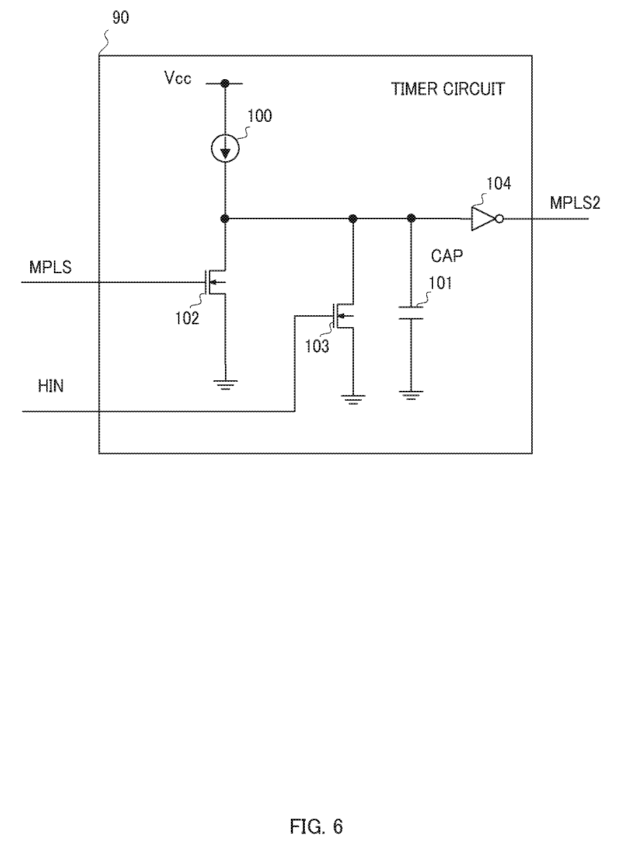

As illustrated in FIG. 6, the timer circuit 90 includes a current source 100, a capacitor 101, NMOS transistors 102 and 103, and an inverter 104. The current source 100 supplies a predetermined current to the capacitor 101. The NMOS transistors 102 and 103 are coupled in series to the current source 100 and are also coupled in parallel to the capacitor 101. Accordingly, the capacitor 101 is charged only when both of the NMOS transistors 102 and 103 are off.

The NMOS transistor 102 is turned on, in response to the high signal MPLS being outputted from the comparator 82 in FIG. 4, and is turned off, in response to the low signal MPLS being outputted from the comparator 82. More specifically, the NMOS transistor 102 is on when the voltage SENSE is lower than the reference voltage Vref (that is, in the case of the state B), and is off when the voltage SENSE is higher than the reference voltage Vref (that is, in the case of the state A).

The NMOS transistor 103 is on when the signal HIN is high and is off when the signal HIN is low. Accordingly, in the timer circuit 90 in this embodiment, the capacitor 101 is charged when the signal HIN is low and the signal MPLS is low (that is, in the case of the state A).

The inverter 104 compares a charge voltage for the capacitor 101 (hereinafter referred to as charge voltage CAP) and a threshold voltage Vth of the inverter 104, and outputs the signal MPLS2 according to the comparison result. Specifically, the inverter 104 outputs the high signal MPLS2 when the charge voltage CAP is lower than the threshold voltage Vth of the inverter 104. On the other hand, the inverter 104 outputs the low signal MPLS2 when the charge voltage CAP is higher than the threshold voltage Vth of the inverter 104.

In this embodiment, a current value of the current source 100 and a capacitance value of the capacitor 101 are set such that a time period from when the signal HIN goes low and the signal MPLS goes low to when the charge voltage CAP reaches the threshold voltage Vth of the inverter 104 is equal to the time period Ta. Thus, the timer circuit 90 outputs the low signal MPLS2, in response to the predetermined time period Ta having elapsed since the signal HIN goes low and the signal MPLS goes low.

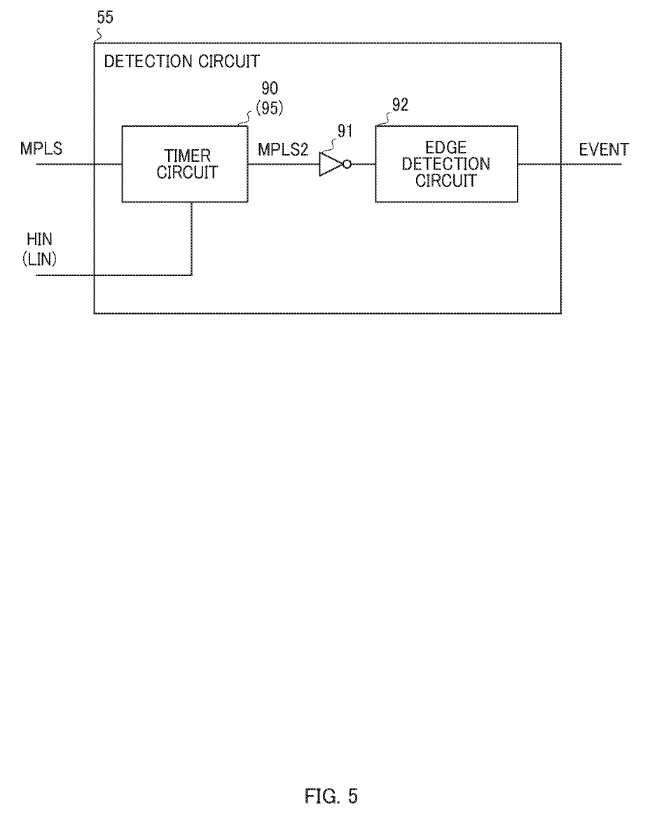

The inverter 91 in FIG. 5 inverts the logic level of the signal MPLS2 and outputs the resultant signal. The edge detection circuit 92 detects a rising edge of the inverter 91 and outputs a high pulsed signal EVENT. Thus, the detection circuit 55 outputs the high pulsed signal EVENT, in response to the state where the signal HIN is low and the voltage SENSE is higher than the reference voltage Vref (that is, the state A) having been kept for the predetermined time period Ta.

The high pulsed signal EVENT is inputted to the signal output circuit 30 illustrated in FIGS. 1 and 3. Here, the inverter 71 of the signal output circuit 30 outputs a high signal when the signal HIN is low. Thus, the high signal EVENT is outputted as the reset signal RSET via the AND circuit 74 and the OR circuit 73.

That is, the signal output circuit 30 outputs the high pulsed reset signal RSET, in response to the state where the signal HIN is low and the voltage SENSE is higher than the reference voltage Vref (that is, the state A) having been kept for the predetermined time period Ta. As a result, the switching control circuit 23 in this embodiment is capable of more reliably turning off the high-side NMOS transistor 20, as will be described later in detail.

### Operations of Switching Control Circuit 23

### Normal Operation

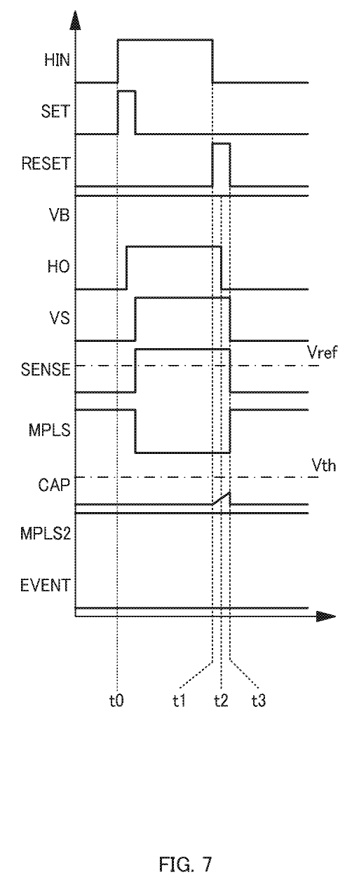

With reference to FIG. 7, an example of a normal operation of the switching control circuit 23 in FIG. 1 is described below. Here, the "normal operation of the switching control circuit 23" means an operation of the switching control circuit 23 when noise that may influence operations of the circuits in the switching control circuit 23 does not occur. Although not illustrated in FIG. 7 for convenience, the NMOS transistor 21 is off before time t0. The voltage VS of the line Ls at time t0 is the ground voltage (0 V) due to influence of the load 15 and the like.

First, when the signal HIN goes high at time t0, the signal output circuit 30 outputs the high pulsed set signal SET. When the set signal SET is outputted, the level shifter circuit 31 outputs the set signal Ss (not illustrated) and thus the driver circuit 33 outputs the high drive signal HO. As a result, the NMOS transistor 20 is turned on and the voltage VS of the line Ls rises to the level of the power supply voltage Vcc (that is, the high level). In addition, since the voltage SENSE obtained by dividing the voltage VS also rises above the reference voltage Vref, the comparator 82 in FIG. 4 outputs the low signal MPLS.

When the signal HIN goes low at time t1, the signal output circuit 30 outputs the high pulsed reset signal RSET. At time t2 after the reset signal RSET is outputted, the drive signal HO goes low. Because the NMOS transistor 20 is turned off when the drive signal HO goes low, the voltage VS falls to the ground voltage (that is, the low level) at timet3. Further, because the voltage SENSE obtained by dividing the voltage VS also falls below the reference voltage Vref, the comparator 82 in FIG. 4 outputs the high signal MPLS.

Here, when the signal HIN goes low at time t1, the capacitor 101 is charged in the timer circuit 90 in FIG. 6 because the signal MPLS is low. Accordingly, the charge voltage CAP gradually rises from time t1. However, here, the signal MPLS goes high at time t3 before the charge voltage CAP reaches the threshold voltage Vth. Thus, the signal MPLS2 from the timer circuit 90 remains high and the detection circuit 55 dose not output the pulsed signal EVENT.

Although omitted in FIG. 7 for convenience, in response to a time period Td corresponding to the so-called dead time having elapsed since time t1, the signal LIN goes high and the low-side NMOS transistor 21 is turned on (see FIG. 2). In this way, in the normal operation, the high-side NMOS transistor 20 is turned on and off based on changes in the logic level of the signal HIN.

### WHEN VOLTAGE VB VARIESF

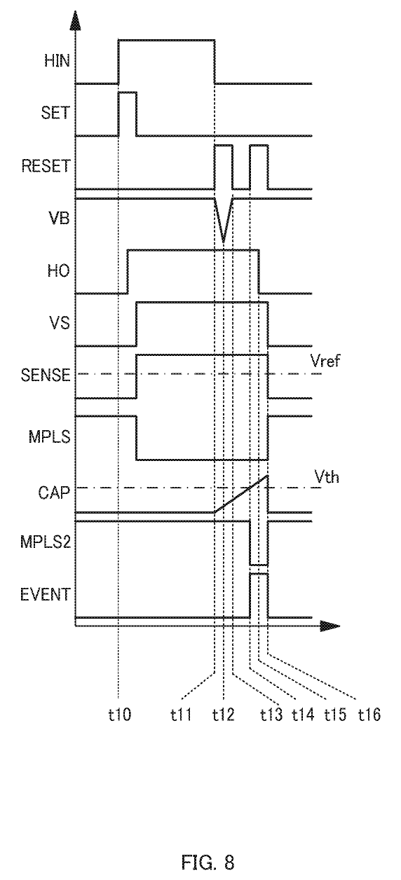

With reference to FIG. 8, an example of an operation of the switching control circuit 23 is described below, when the voltage VB varies due to noise of a negative voltage or the like. In FIG. 8, the operation from time t10 to time t11 is the same as that from time t0 to timet1 in FIG. 7, and accordingly detailed description thereof is omitted herein.

At timet11, when the signal HIN goes low, the signal output circuit 30 in FIG. 1 outputs the high pulse reset signal RSET. Here, in time t11 to time t13, if the voltage VB drops due to influence of noise or the like, the level shifter circuit 31 fails to level-shift the reset signal RSET properly. Accordingly, the driver circuit 33 fails to change the drive signal HO low. Thus, the NMOS transistor 20 continuously remains on.

Further, at time t11, the voltage VS and the voltage SENSE are high, and thus the signal MPLS is low. Accordingly, the capacitor 101 is charged in the timer circuit 90 in FIG. 6. Thus, after time t11, the charge voltage CAP gradually rises. At time t14, the charge voltage CAP reaches the threshold voltage Vth and thus the signal MPLS2 goes low. When the signal MPLS2 goes low, the detection circuit 55 outputs the high pulsed signal EVENT.

At time t14, the signal HIN is low, and thus the signal output circuit 30 in FIG. 2 outputs the reset signal RSET in response to the output of the high pulsed signal EVENT. Accordingly, at time t15, the driver circuit 33 changes the drive signal HO low, and thereby turning off the NMOS transistor 20. Thus, at time t16, the voltage VS falls to the ground voltage (that is, the low level) and the voltage SENSE also falls below the reference voltage Vref.

When the voltage SENSE falls below the reference voltage Vref, the determination circuit 54 in FIG. 4 changes the signal MPLS high. Accordingly, in the timer circuit 90 in FIG. 6, the NMOS transistor 102 is turned on. Thus, the capacitor 101 is discharged and the voltage CAP falls to substantially zero.

Here, in response to the time period Td corresponding to the so-called dead time having elapsed since time t11, the signal LIN goes high and the low-side NMOS transistor 21 is turned on (see FIG. 2).

In this way, even when the voltage VB varies due to noise and the reset signal RSET fails to be transmitted properly (for example, at time t12), the signal output circuit 30 in this embodiment outputs the reset signal RSET again (for example, at time t14). Thus, in this embodiment, it is possible to turn off the high-side NMOS transistor 20 even when there is influence of noise.

Further, the driver circuit 34 turns off the NMOS transistor 21 in response to the signal EVENT. Accordingly, in this embodiment, it is possible to prevent both of the NMOS transistors 20 and 21 from turning on and a shoot-through current from flowing through the NMOS transistors 20 and 21.

### Case that Voltage VS Varies

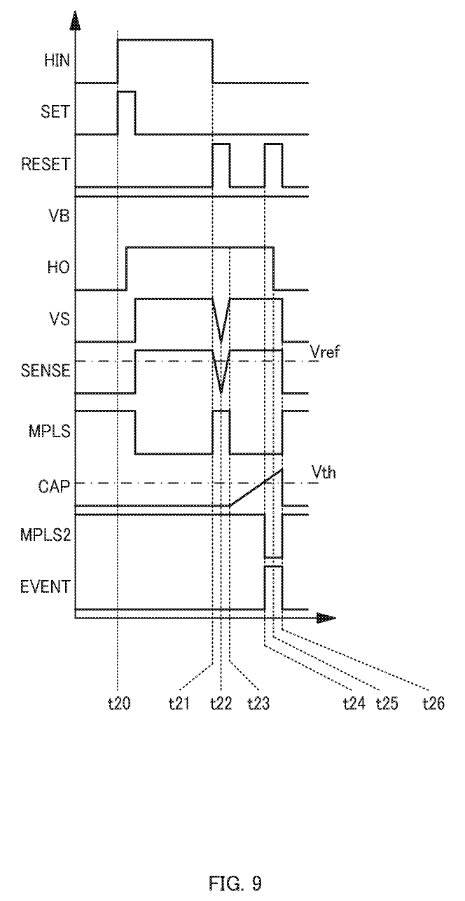

With reference to FIG. 9, an example of an operation of the switching control circuit 23 is described below which the voltage VS varies due to noise of a negative voltage or the like. In FIG. 9, the operation from timet 21 to timet 21 is the same as that from time t0 to time t1 in FIG. 7, and accordingly detailed description thereof is omitted herein.

At timet21, when the signal HIN goes low, the signal output circuit 30 in FIG. 1 outputs the high pulse-form reset signal RSET. Here, in time t21 to time t23, if the voltage VS drops due to influence of noise or the like, the level shifter circuit 31 fails to level-shift the reset signal RSET properly. For this reason, the driver circuit 33 fails to change the drive signal HO low. As a result, the NMOS transistor 20 continuously remains on.

Further, in time t21 to time t23, in response to the voltage VS dropping, the voltage SENSE also drops below the reference voltage Vref. Accordingly, the determination circuit 54 in FIG. 4 outputs the high signal MPLS. Here, at time t21, the signal HIN goes low, but the signal MPLS goes high, and thus the capacitor 101 in the timer circuit 90 in FIG. 6 is continuously discharged.

Then, at time t23, when the voltage VS is restored, the voltage SENSE rises above the reference voltage Vref. Accordingly, after time t23, the charge voltage CAP gradually rises. Then, at time t24, the charge voltage CAP reaches the threshold voltage Vth and thus the signal MPLS2 goes low. When the signal MPLS2 goes low, the detection circuit 55 outputs the high pulsed signal EVENT.

At time t24, the signal HIN is low, and thusin response to the high pulsed signal EVENT being outputted, the signal output circuit 30 in FIG. 2 outputs the reset signal RSET. Accordingly, at time t25, the driver circuit 33 changes the drive signal HO low, and thereby turning off the NMOS transistor 20. Thus, at time t26, the voltage VS falls to the ground voltage (that is, the low level) and the voltage SENSE also falls below the reference voltage Vref.

When the voltage SENSE falls below the reference voltage Vref, the determination circuit 54 in FIG. 4 changes the signal MPLS high. Accordingly, the NMOS transistor 102 is turned on in the timer circuit 90 in FIG. 6. Thus, the capacitor 101 is discharged and the voltage CAP falls to substantially zero.

Here, in response to the time period Td corresponding to the so-called dead time having elapsed since time t21, the signal LIN goes high and the low-side NMOS transistor 21 is turned on (see FIG. 2).

In this way, even when the voltage VS varies due to noise and the reset signal RSET fails to be transmitted properly (for example, at time t22), the signal output circuit 30 in this embodiment outputs the reset signal RSET again (for example, at time t24). Accordingly, in this embodiment, it is possible to turn off the high-side NMOS transistor 20 even when there is influence of noise.

The driver circuit 34 turns off the NMOS transistor 21 in response to the signal EVENT. Thus, in this embodiment, it is possible to prevent both of the NMOS transistors 20 and 21 from turning on and a shoot-through current from flowing through the NMOS transistors 20 and 21.

### Second Embodiment

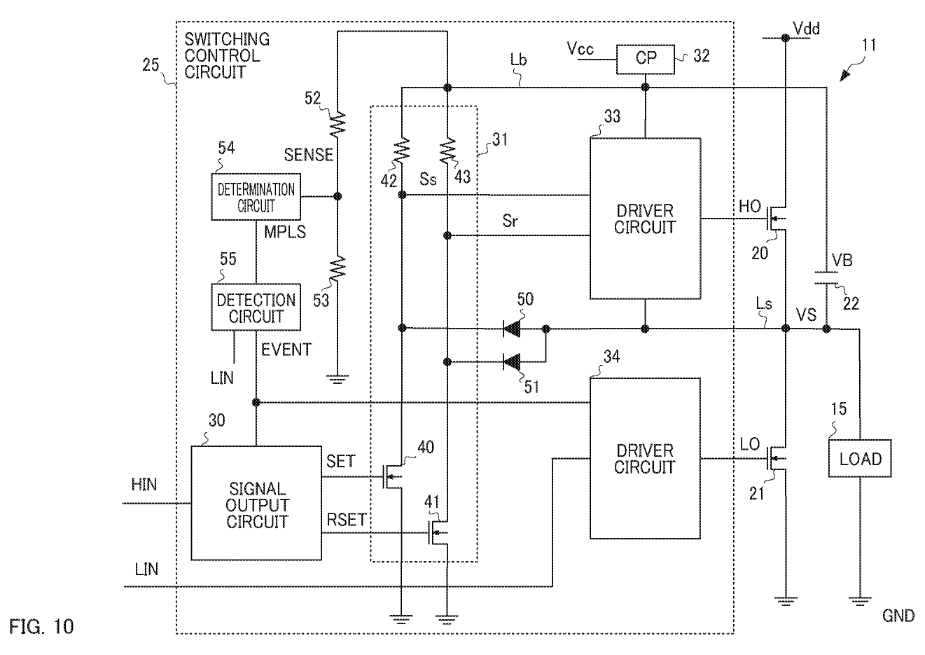

FIG. 10 is a diagram for explaining an example of a semiconductor module 11 in a second embodiment. The semiconductor module 11 is a semiconductor device configured to drive a load 15 such as a coil based on an instruction from a microcomputer (not illustrated) as in the semiconductor module 10, and includes NMOS transistors 20 and 21, a capacitor 22, and a switching control circuit 25.

The switching control circuit 25 is similar to the switching control circuit 23 in FIG. 1, but is different therefrom in that the resistor 52 is coupled to the line Lb instead of the line Ls, and the detection circuit 55 includes a timer circuit 95 configured to operate based on the signal LIN. Thus, the following describes mainly about the resistors 52 and 53 and the timer circuit 95.

In the switching control circuit 25, the resistors 52 and 53 configure a voltage divider circuit to divide the voltage VB and output the resultant voltage as the voltage SENSE. Even in such embodiment, the determination circuit 54 can determine whether the state of the line Ls is a state where the high-side NMOS transistor 20 is on (hereinafter referred to as a state A) or a state where the low-side NMOS transistor 21 is on (hereinafter referred to as a state B). Accordingly, even when using the configuration where the resistors 52 and 53 divide the voltage VB, it is possible to obtain the same effect as in the first embodiment.

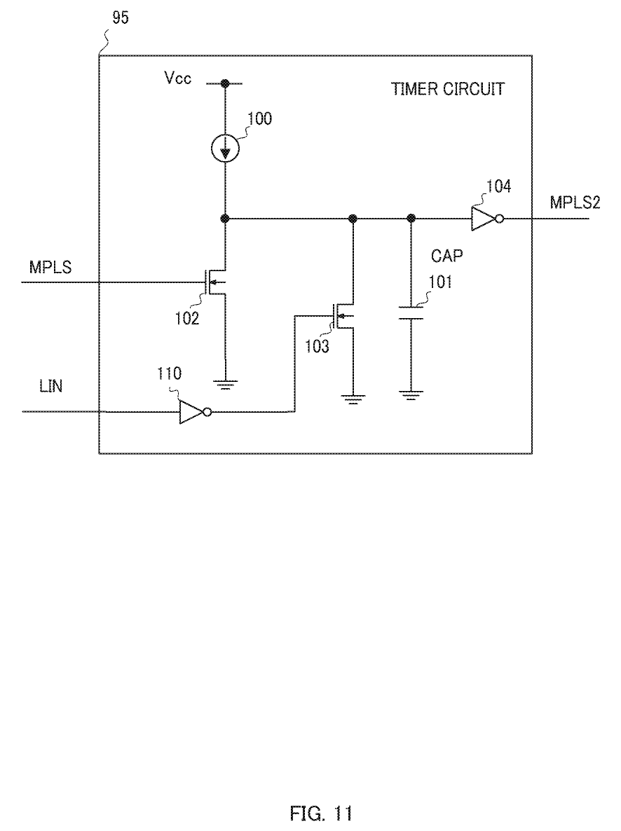

The timer circuit 95 illustrated in FIG. 11 outputs the low signal MPLS2, when a time period for which the low signal MPLS is outputted in the state after the signal HIN goes low, that is, the state where the signal LIN is high, reaches a predetermined time period Ta. When the timer circuit 95 in FIG. 11 and the timer circuit 90 are compared, they have the same configuration except for an inverter 110. Even when using the timer circuit 95 having such configuration, it is possible to obtain the same effect as in the first embodiment.

### SUMMARY

Hereinabove, the semiconductor modules 10 and 11 in the present embodiments are described. In the semiconductor module 10, even after the signal HIN goes low, the high-side NMOS transistor 20 is not turned off and thus the voltage SENSE is higher than the reference voltage Vref, in some cases, due to influence of noise or the like. In this embodiment, when the state where the voltage SENSE is higher than the reference voltage Vref (that is, the state A) has been kept for the predetermined time period Ta, the signal output circuit 30 outputs the reset signal RSET. This enables the switching control circuit 23 to turn off the high-side NMOS transistor 20 even when noise or the likeoccurs.

Further, the determination circuit 54 in FIG. 1 is capable of determining whether the voltage SENSE is higher than the reference voltage Vref (that is, in the state A), for example, based on the voltage VS.

Further, the determination circuit 54 in FIG. 10 is capable of determining whether the voltage SENSE is higher than the reference voltage Vref (that is, in the state A), for example, based on the voltage VB.

In the present embodiments, the predetermined time period Ta is set to be longer than the time period Td corresponding to the so-called dead time. Thus, the switching control circuit 23 is capable of turning off the high-side NMOS transistor 20 when the low-side NMOS transistor 21 is turned on.

The low-side driver circuit 34 in the present embodiments turns off the NMOS transistor 21 based on the signal EVENT. Thus, in the present embodiments, it is possible to prevent a shoot-through current from flowing through the NMOS transistors 20 and 21.

The present disclosure is directed to provision of a switching control circuit capable of turning off a high-side switching device even when noise or the like occurs.

According to the present disclosure, it is possible to provide a switching control circuit capable of turning off a high-side switching device even when noise or the like occurs.

Embodiment(s) of the present disclosure described above is/are simply to facilitate understanding of the present disclosure and is/are not in any way to be construed as limiting the present disclosure. The present disclosure may variously be changed or altered without departing from its essential features and encompass equivalents thereof.

What is claimed is:

1. A switching control circuit configured to complementarily turn on and off
a first switching device on a power supply side, and
a second switching device on a ground side, the second switching device being configured to drive a load with the first switching device,
the switching control circuit comprising:
a signal output circuit configured to
receive a first input signal,
output a set signal to turn on the first switching device, in response to a first input signal turning to a first logic level, and
output a reset signal to turn off the first switching device, in response to the first input signal turning to a second logic level;
a level shifter circuit configured to level-shift the set signal and the reset signal;
a first line to which the first switching device and the second switching device are coupled;
a first driver circuit coupled to the first line, and configured to drive the first switching device based on an output from the level shifter circuit;
a determination circuit configured to determine whether the first line is in
a first state, in which the first switching device is on, or
a second state, in which the second switching device is on; and
a detection circuit configured to detect whether a time period, for which the first line is in the first state after the first input signal turns to the second logic level, reaches a predetermined time period,
the signal output circuit being configured to output the reset signal, in response to the time period reaching the predetermined time period.

2. The switching control circuit according to claim 1, wherein
the determination circuit determines whether the first line is in the first state or the second state, based on a voltage of the first line.

3. The switching control circuit according to claim 1, further comprising
a second line configured to receive a power supply voltage to operate the first driver circuit, wherein
the determination circuit determines whether the first line is in the first state or the second state, based on a voltage of the second line.

4. The switching control circuit according to claim 1, wherein
the predetermined time period is longer than another time period for which both of the first switching device and the second switching device are off.

5. The switching control circuit according to claim 4, further comprising
a second driver circuit configured to receive a second input signal and to drive the second switching device in response to the second input signal, wherein
the second driver circuit turns off the second switching device, in response to the time period reaching the predetermined time period.

6. A semiconductor device, comprising:
a first switching device on a power supply side of the semiconductor device;
a second switching device on a ground side of the semiconductor device, the second switching device being configured to drive a load of the semiconductor device with the first switching device; and
a switching control circuit configured to complementarily turn on and off the first and second switching devices,
the switching control circuit including
a signal output circuit configured to
output a set signal to turn on the first switching device, in response to a first input signal turning to a first logic level, and
output a reset signal to turn off the first switching device, in response to the first input signal turning to a second logic level,
a level shifter circuit configured to level-shift the set signal and the reset signal,
a first line to which the first switching device and the second switching device are coupled,
a first driver circuit coupled to the first line, and configured to drive the first switching device based on an output from the level shifter circuit,
a determination circuit configured to determine whether the first line is in
a first state, in which the first switching device is on, or
a second state, in which the second switching device is on, and
a detection circuit configured to detect whether a time period, for which the first line is in the first state after the first input signal turns to the second logic level, reaches a predetermined time period,
the signal output circuit being configured to output the reset signal in response to the time period reaching the predetermined time period.
